(19) United States
(12) Patent Application Publication
(10) Pub. No.: US 2026/0289368 A1
(43) Pub. Date: Sep. 24, 2026

(54) QUANTUM COMPUTING APPARATUS

(71) Applicant: Samsung Electronics Co., Ltd., Suwon-si (KR)

(72) Inventors: Jaehyeong LEE, Suwon-si (KR); Daeyun KIM, Suwon-si (KR); Taekjung KIM, Suwon-si (KR); Dongjoon LEE, Suwon-si (KR); Won Joon CHO, Suwon-si (KR)

(73) Assignee: Samsung Electronics Co., Ltd., Suwon-si (KR)

(21) Appl. No.: 19/048,349

(22) Filed: Feb. 7, 2025

(30) Foreign Application Priority Data
Feb. 8, 2024 (KR) 10-2024-0019880
Sep. 23, 2024 (KR) 10-2024-0128263

(51) Int. Cl. G06N 10/40

(52) U.S. Cl. CPC G06N 10/40

(57) ABSTRACT

A quantum computing apparatus includes a substrate, a superconducting quantum interferometric device (SQUID) disposed on the substrate and including Josephson junction devices, a magnetic field generator configured to form a magnetic field for controlling frequencies of the Josephson junction devices, and a superconducting shield structure configured to shield part of a magnetic field formed by the magnetic field generator, and including a superconducting material and an opening.

### CROSS-REFERENCE TO RELATED APPLICATIONS

This application is based on and claims priority under 35 U.S.C. § 119 to Korean Patent Application No. 10-2024-0019880, filed on Feb. 8, 2024, and Korean Patent Application No. 10-2024-0128263, filed on Sep. 23, 2024, in the Korean Intellectual Property Office, the disclosures of which are incorporated by reference herein in their entirety.

### BACKGROUND

### 1. Field

One or more embodiments relate to a quantum computing apparatus.

### 2. Description of Related Art

A quantum computer is a computational device that uses quantum mechanical phenomena such as quantum superposition and quantum entanglement as operating principles to perform data processing. A unit device capable of storing information by using quantum mechanical principles (or the information itself) is called a quantum bit or a qubit, and may be used as a basic unit of information in a quantum computer.

As interest in quantum computers increases, research on various types of qubits has been conducted. Qubits may be implemented in various types such as photon qubits, ion trap qubits, topological qubits, and superconducting qubits.

Qubits using superconductors (that is, superconducting qubits) have merits in that manufacturing superconducting qubits as integrated circuits is relatively easy. A qubit chip of a superconducting qubit type typically includes a Josephson junction element and various RF circuits. For example, a superconducting quantum interferometric device (SQUID) in which two Josephson junctions are connected in parallel may be provided in a qubit chip.

The qubit chip also typically includes a current line that forms a magnetic field to control the frequency of a qubit. Such a current line is arranged adjacent to a SQUID so as to form a magnetic field in a loop formed by the SQUID, and accordingly, crosstalk and RF noise may occur.

### SUMMARY

An embodiment of the present disclosure provides a quantum computing apparatus having reduced crosstalk due to a magnetic field generator.

Additional aspects will be set forth in part in the description which follows and, in part, will be apparent from the description, or may be learned by practice of the presented embodiments of the disclosure.

In one general aspect, a quantum computing apparatus includes a substrate, a superconducting quantum interferometric device (SQUID) disposed on the substrate and including a Josephson junction device, a magnetic field generator forming a magnetic field that controls what frequency the Josephson junction device operates with, and a superconducting shield structure that shields part of a magnetic field formed by the magnetic field generator, where the superconducting shield structure includes a superconducting material and an opening.

The magnetic field generator may be spaced apart from the substrate in a direction perpendicular to a plane of the substrate, and the superconducting shield structure may be arranged between the substrate and the magnetic field generator.

The quantum computing apparatus may further include an insulating material layer arranged between the magnetic field generator and the superconducting shield structure.

The superconducting quantum interferometric device may have a shape forming a loop, and a position and a size of the opening in the superconducting shield structure may be configured so that a magnetic field is generated in the loop of the SQUID by the magnetic field generator.

The magnetic field generator may include a superconducting line that includes a superconducting material and provides a current path in a first direction that is parallel to a planar surface of the substrate.

When viewed from a second direction that is perpendicular to the planar surface of the substrate, a center of the superconducting shield structure and a center of the SQUID may be not aligned with each other.

The opening of the superconducting shield structure and the SQUID may be arranged so as not to overlap each other when viewed from the second direction.

The magnetic field generator may include a ferromagnetic substance forming a magnetic field due to an applied voltage.

The ferromagnetic substance may have magnetic anisotropy in a direction perpendicular to a planar surface of the substrate.

The ferromagnetic substance may be arranged to face the opening of the superconducting shield structure.

The opening of the superconducting shield structure may be arranged to face the SQUID.

The quantum computing apparatus may include a plurality of SQUIDs.

In the superconducting shield structure the opening may be one of multiple openings in the superconducting shield structure.

The magnetic field generator may include ferromagnetic substances facing the openings in one-to-one correspondence.

The openings may be arranged to face the SQUIDs in one-to-one correspondence.

The quantum computing apparatus may further include interconnections for individually applying a voltage to each of the ferromagnetic substances.

The quantum computing apparatus may further include an insulating material layer arranged on the superconducting shield structure so as to surround the ferromagnetic substances.

The interconnections may extend to be exposed to one side surface of the insulating material layer.

The magnetic field generator may include superconducting lines.

When viewed from a direction perpendicular to a planar surface of the substrate, centers of the respective openings and centers of the respective SQUIDs may be not aligned with each other.

Other features and aspects will be apparent from the following detailed description, the drawings, and the claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of the structure of a quantum computing apparatus according to one or more embodiments;

FIG. 2 shows a circuit analogue of a qubit device of the quantum computing apparatus of FIG. 1;

FIG. 3 is a plan view of an example shape of a superconducting shield structure provided in the quantum computing apparatus of FIG. 1;

FIG. 4A is a plan view of a quantum computing apparatus according to a comparative example;

FIG. 4B is a cross-sectional view of the quantum computing apparatus taken along line A-A′ of FIG. 4A;

FIG. 4C is a conceptual diagram showing generation of RF-noise in a quantum computing apparatus according to a comparative example;

FIG. 5 shows an example equivalent circuit formed by a quantum computing apparatus according to a comparative example;

FIG. 6 is a plan view showing a first chip device in a quantum computing apparatus according to one or more embodiments;

FIG. 7 is a diagram conceptually showing blocking of RF-noise in a quantum computing apparatus according to one or more embodiments;

FIG. 8 is a cross-sectional view of a quantum computing apparatus according to one or more embodiments;

FIG. 9 is a plan view of an example structure of a superconducting shield structure provided in the quantum computing apparatus of FIG. 8;

FIG. 10 is a cross-sectional view of a quantum computing apparatus according to another embodiment;

FIG. 11 is a cross-sectional view of a quantum computing apparatus according to another embodiment;

FIG. 12 is a plan view of an example structure of a superconducting shield structure provided in the quantum computing apparatus of FIG. 11;

FIG. 13 is a plan view of an example of an arrangement of ferromagnetic substances in the quantum computing apparatus of FIG. 11;

FIG. 14 is a cross-sectional view of a quantum computing apparatus according to one or more embodiments;

FIG. 15 is a plan view of the quantum computing apparatus of FIG. 14 as viewed from above;

FIG. 16 is a cross-sectional view showing a quantum computing apparatus according to one or more embodiments;

FIG. 17 is a plan view of the quantum computing apparatus of FIG. 16 as viewed from above; and

FIG. 18 is a cross-sectional view of a quantum computing apparatus according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

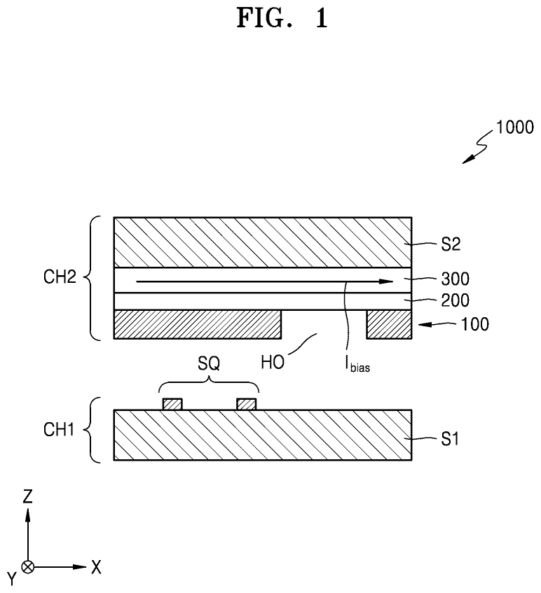

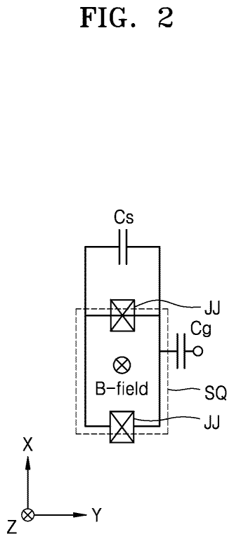

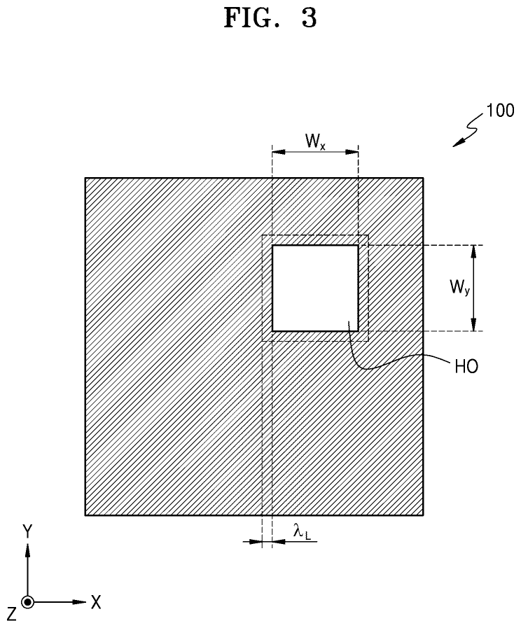

FIG. 1 is a cross-sectional view of a quantum computing apparatus 1000 according to an embodiment, and FIG. 2 is a diagram showing a circuit analogue of a qubit device in the quantum computing apparatus 1000 of FIG. 1. FIG. 3 is a plan view of a superconducting shield structure provided in the quantum computing apparatus 1000 of FIG. 1.

The quantum computing apparatus 1000 includes a superconducting quantum interferometric device (SQUID) SQ including a Josephson junction device, a magnetic field generator forming a magnetic field for controlling the frequency of the Josephson junction device, and a superconducting shield structure 100 shielding/blocking a portion of the magnetic field formed by the magnetic field generator. The magnetic field generator may include a superconducting line 300.

The SQUID SQ may be formed on a first substrate S1. The SQUID SQ may include two Josephson junctions that are connected in parallel. Circuit elements electrically connected with the SQUID SQ may be provided on the first substrate S1. The first substrate S1 and the SQUID SQ and the circuit elements formed on the first substrate S1 form a first chip device CH1.

The superconducting line 300 included in the magnetic field generator and the superconducting shield structure 100 may be formed on a second substrate S2. A current I_{bias} may be applied to the superconducting line 300. The current direction may be a first direction (X-direction) that is parallel (or co-planar) to the second substrate S2. An insulating material layer 200 may be arranged between the superconducting line 300 and the superconducting shield structure 100. The superconducting line 300, the insulating material layer 200, and the superconducting shield structure 100 formed on the second substrate S2 form a second chip device CH2.

The first substrate S1 and the second substrate S2 may be silicon substrates. Alternatively, the first and second substrates may each include a silicon on insulator (SOI) substrate, a sapphire substrate, and an insulating substrate of other various materials.

The quantum computing apparatus 1000 uses an induced current magnetic field for controlling the frequency of the qubit, and the qubit and the magnetic field generator for controlling the frequency of the qubit are provided on separate substrates. The first chip device CH1 (including the qubit) and the second chip device CH2 (generating a magnetic field applied to the qubit) may be spaced apart from each other in a second direction (Z-direction) perpendicular to the first substrate S1, as shown in the drawings. That is, the SQUID SQ and the superconducting line 300 forming the magnetic field in the SQUID SQ are arranged on separate substrates that are spaced apart from each other in the second/Z direction.

Referring to FIG. 2, the SQUID SQ may include two Josephson junction devices JJ that are connected in parallel to form a loop. Each of the Josephson junction devices JJ may include a pair of superconducting material layers facing each other and a non-superconducting material layer disposed/sandwiched therebetween, for example, a dielectric layer. Alternatively, the Josephson junction device JJ may include a pair of superconducting material patterns facing each other, and an air gap inserted between the pair of superconducting material patterns. The circuit elements electrically connected to the SQUID SQ include interconnections forming a readout circuit, and may include a coplanar waveguide resonator for readout, I/O transmission lines, etc., which may be represented as equivalent capacitors.

The magnetic field generator may form a magnetic field (B-field) in a loop formed by the SQUID SQ. The magnetic field generator includes the superconducting line 300, and the superconducting line 300 may provide a current path in a direction expressed as I_{bias}. The superconducting line 300 may include a superconducting material, as non-limiting examples, aluminum (Al), neobium (Nb), indium (In), alpha-tantalum (a-Ta), titanium (Ti), lead (Pb), vanadium (V), or a compound thereof, for example, NbN, NbTiN, TiN, or VN. As used herein, “superconducting” also refers to materials that can become superconducting under appropriate conditions.

The superconducting shield structure 100 may be made of a superconducting material. The superconducting material has a function of shielding magnetic field (i.e., functions as a magnetic shield). The superconducting material may be deposited in a thin film, and may be formed in a desired pattern. Therefore, the superconducting material may be designed in a desired pattern, for example, in a shape having one or more fine holes, and may control a magnetic field around the fine holes.

The superconducting material included in the superconducting shield structure 100 may include aluminum (Al), niobium (Nb), indium (In), alpha-tantalum (a-Ta), titanium (Ti), lead (Pb), vanadium (V), or a compound thereof, as non-limiting examples. The superconducting shield structure 100 may have a shape including an opening/hole HO. A flux bias line formed by the superconducting line 300 is functionally exposed via the opening HO, and in the region of the superconducting shield structure 100 other than the opening HO, the flux bias line is functionally blocked by the superconducting material included in the superconducting shield structure 100.

The opening HO of the superconducting shield structure 100 and the SQUID SQ may be arranged unaligned with each other (e.g., off-center) when viewed from the second direction (Z-direction) perpendicular to the plane of the first substrate S1. In other words, a center of the opening HO and a center of the SQUID SQ may not be aligned with each other. As shown in FIG. 1, the opening HO of the superconducting shield structure 100 and the SQUID SQ may not overlap each other when viewed from the second direction (Z-direction). However, the embodiment is not limited to the above example, and the opening HO of the superconducting shield structure 100 and a portion of the SQUID SQ may partially overlap each other in the second direction (Z-direction).

A location of the opening HO of the superconducting shield structure 100 is shown in FIG. 3, which conceptually depicts the center of the opening HO and the SQUID SQ arranged so as not to aligned; the location of the opening HO is not limited to this example.

A shape or size of the opening HO may be determined so that a desired magnetic field is formed in the loop of the SQUID SQ and the influence of the magnetic field on the other circuit elements is reduced. The opening HO may have a rectangular shape as shown in the drawing, but is not limited thereto. The shield may have multiple openings HO. The sizes or shapes of the openings may be different from one another.

When setting the size of the opening(s) HO, a London penetration depth λ_{L} may be considered. The London penetration depth is an exclusive magnetic field transmission depth defined by a physical property of a superconducting material. Accordingly, when forming the opening HO of a rectangular shape having a transverse width Wx (see FIG. 3) and a longitudinal width Wy as shown in the drawing, a rectangular area having a transverse width Wₓ+2λ_{L} and a longitudinal width W_{y}+2λ_{L} may be the region through which the magnetic field transmits.

Due to the superconducting shield structure 100 arranged adjacent to the superconducting line 300 included in the magnetic field generator, a desired magnetic field is formed in the loop of the SQUID SQ, and corresponding RF-noise affecting other circuit elements may be minimized.

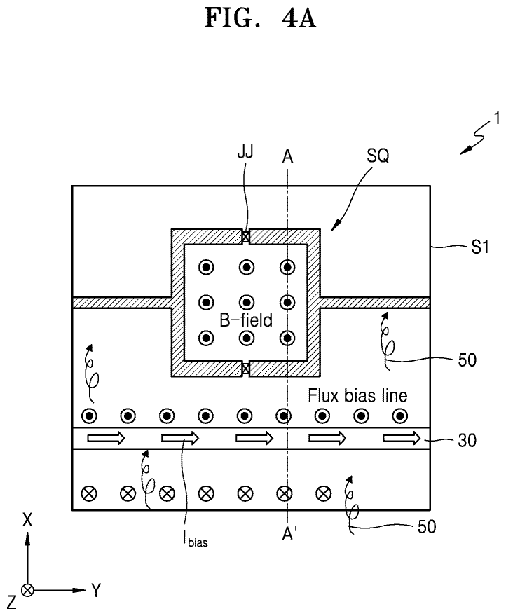

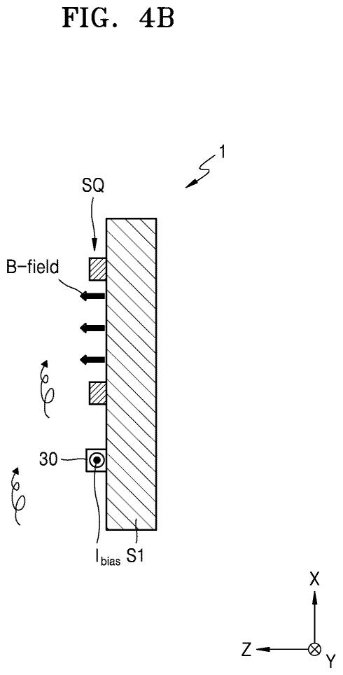

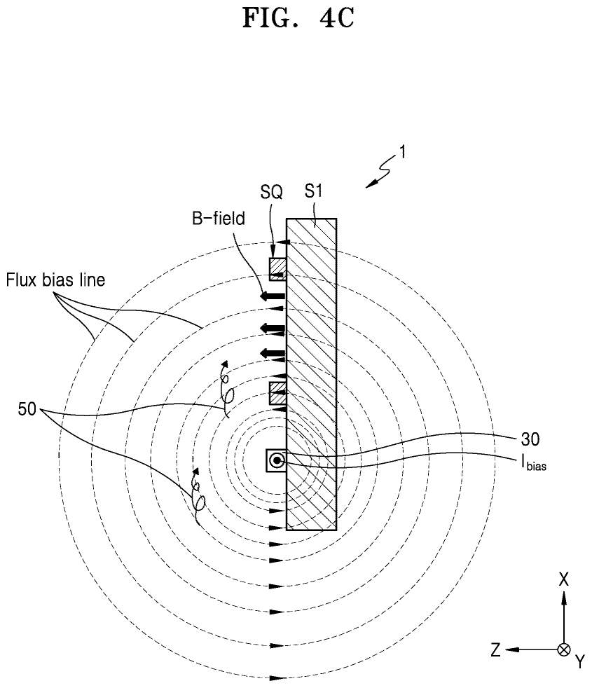

FIG. 4A is a plan view of a quantum computing apparatus 1 according to a comparative example. FIG. 4B is a cross-sectional view of the quantum computing apparatus 1 taken along line A-A′ of FIG. 4A, and FIG. 4C shows an example of a flux bias line in the cross-sectional view of FIG. 4B.

The quantum computing apparatus 1 according to the comparative example includes a SQUID SQ and a magnetic field generator 30.

Unlike the quantum computing apparatus 1000, in the quantum computing apparatus 1 of the comparative example, the SQUID SQ and the magnetic field generator 30 are arranged adjacent to each other on one substrate S1. Accordingly, the flux bias line formed by the current I_{bias} of the magnetic field generator 30 forms the magnetic field B-field in the loop of the SQUID SQ, and moreover, transfers RF-noise 50 to another circuit element adjacent to the SQUID SQ.

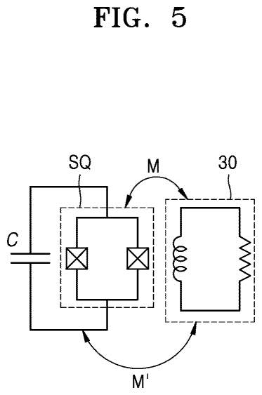

FIG. 5 shows an example of a circuit analog of the quantum computing apparatus 1.

The current line included in the magnetic field generator 30 has a mutual inductance M in a relationship with the SQUID SQ. The SQUID SQ is controlled by induced current from the magnetic field. The current line may have a mutual inductance M′ in a relationship with another circuit element, which may be a cause of the noise.

The structure of the comparative example may be difficult to expand to multiple qubits, due to the factors such as magnetically induced crosstalk and due to the qubits being difficult to be arrange densely because the current line for magnetic induction and qubits are arranged on the same substrate.

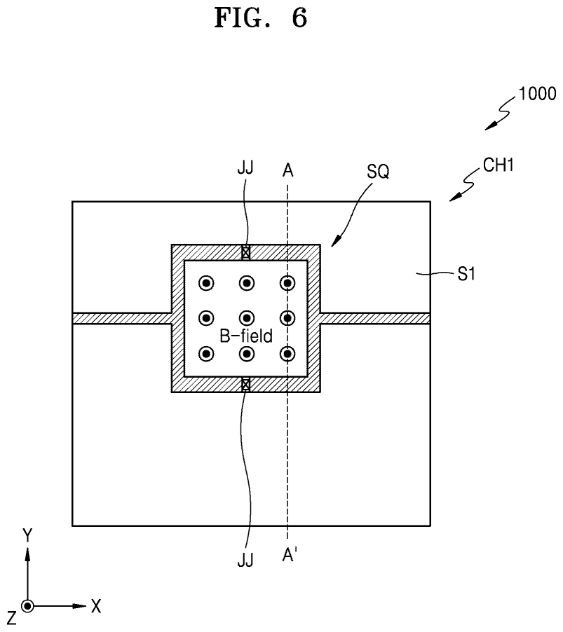

FIG. 6 is a plan view of the first chip device CH1 including the SQUID SQ in the quantum computing apparatus 1000 according to one or more embodiments.

Referring to FIG. 6, the quantum computing apparatus 1000 does not have a current line arranged adjacent to the SQUID SQ on the substrate S1, unlike the comparative example of FIG. 4A. Therefore, as shown in FIG. 4C, the RF-noise 50 (as in the comparative example) does not occur.

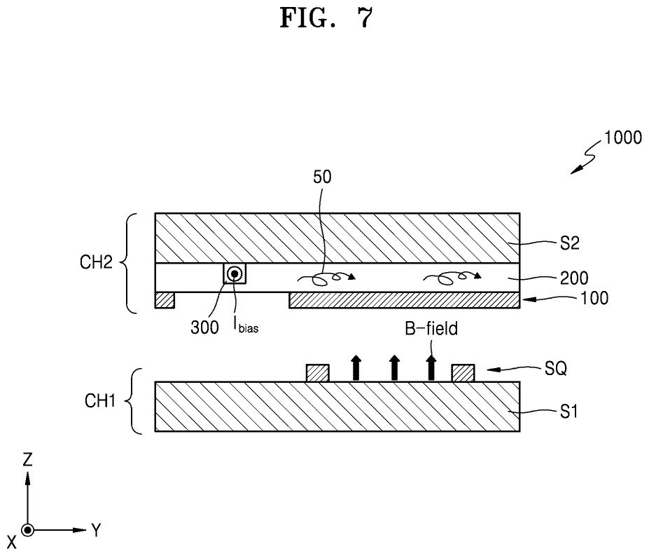

FIG. 7 shows another cross-sectional view of the quantum computing apparatus 1000 (a different cross-section than that of FIG. 1), and conceptually shows the RF-noise 50 being blocked.

The superconducting line 300 in the magnetic field generator forms a magnetic field B-field in a loop of the SQUID SQ due to the current I_{bias} applied thereto. Also, a flux bias line in a different location, which is formed by the superconducting line 300, is blocked by the superconducting shield structure 100 and the RF-noise 50 does not reach the adjacent circuit elements.

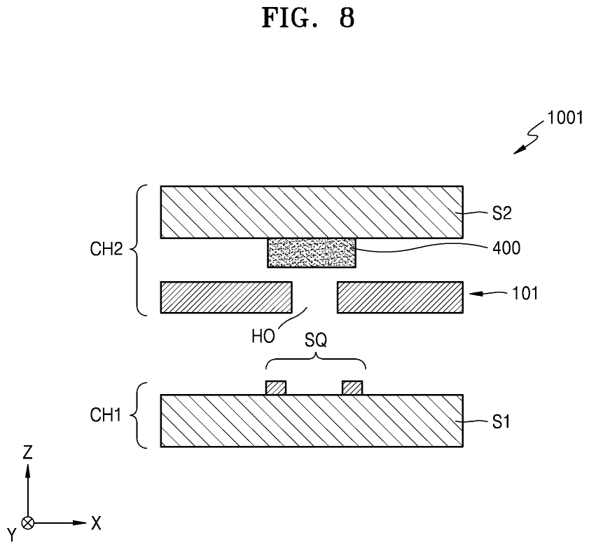

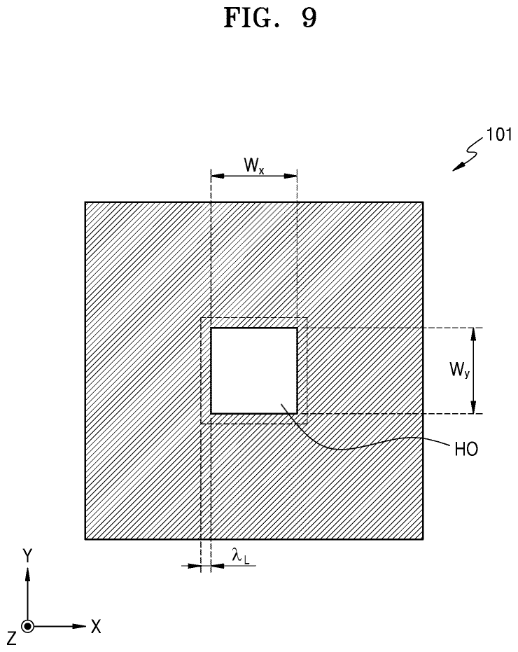

FIG. 8 is a cross-sectional view of a quantum computing apparatus 1001 according to one or more embodiments. FIG. 9 is a plan view of an example of a superconducting shield structure provided in the quantum computing apparatus 1001 of FIG. 8.

The quantum computing apparatus 1001 includes the first chip device CH1 and the second chip device CH2 spaced apart from each other in a second direction (Z-direction).

The first chip device CH1 includes the first substrate S1 and the SQUID SQ disposed on the first substrate S1.

The second chip device CH2 includes: the second substrate S2; a superconducting shield structure 101 formed on the second substrate S2; a magnetic field generator; and the opening HO. The magnetic field generator includes a ferromagnetic substance 400. The ferromagnetic substance 400 may generate a flux bias line (magnetic field line) at a position adjacent to the ferromagnetic substance 400 because a saturation magnetization density thereof is changed by the applied voltage. The ferromagnetic substance 400 may have a perpendicular magnetic anisotropy. A direction of the magnetic anisotropy may be the second direction (Z-direction), which is perpendicular to the first direction (X-direction), which itself is parallel to the surface of the first substrate S1. According to a sign/direction of voltage applied to the ferromagnetic substance 400 in the direction of the perpendicular magnetic anisotropy, that is, the second direction, the saturation magnetization density may be increased or decreased. For example, the saturation magnetization density may increase when a positive voltage is applied, and the saturation magnetization density may decrease when a negative voltage is applied.

The ferromagnetic substance 400 is shown to have a single layer for convenience of description, but the ferromagnetic substance 400 may have a multi-layered structure. The ferromagnetic substance 400 may include multi-layered magnetic material. The ferromagnetic substance 400 may further include other magnetic material layer(s) in addition to the magnetic material having the perpendicular magnetic anisotropy. The ferromagnetic substance 400 may include, as non-limiting examples, a GdCo layer having the perpendicular magnetic anisotropy, and may further include Pd, NiO, GdOx layers, etc. adjacent to the GdCo layer.

The ferromagnetic substance 400 may be spaced apart from the superconducting shield structure 101. The separation distance may be determined in consideration of a flux line shape of the magnetic field formed by the ferromagnetic substance 400. In another embodiment, an insulating material layer may be further arranged between the ferromagnetic substance 400 and the superconducting shield structure 101.

The opening HO of the superconducting shield structure 101 may be located to face the SQUID SQ. The opening HO of the superconducting shield structure 101 and the SQUID SQ may be arranged to entirely overlap each other when seen in the second direction (Z-direction). However, embodiments are not limited to the above example. A center of the opening HO and a center of the SQUID SQ may be aligned when seen in the second direction (Z-direction). However, embodiments are not limited to the above example.

As described above in the description about the opening HO of the superconducting shield structure 100, the shape, position, size, etc. of the opening HO of the superconducting shield structure 101 may be set so that the magnetic field is formed in the loop of the SQUID SQ while the noise transferred to the other circuit elements adjacent to the SQUID SQ may be reduced.

The magnetic field generator has a structure including the ferromagnetic substance 400 and may form a flux bias line that is different type from the flux bias line formed by the magnetic field generator of the quantum computing apparatus 1000 as shown in FIG. 1 according to the current I_{bias} applied to the superconducting line 300. In this point of view, the position and/or size of the opening HO formed in the superconducting shield structure 101 may be different from the position and/or size of the opening HO formed in the superconducting shield structure 100 of FIG. 1.

As shown in FIG. 9, the size of the opening HO may be set in consideration of the London penetration depth λ_{L}. That is, a horizontal width Wₓ and a longitudinal width W_{y} of the opening HO may be determined so that a horizontal width and a longitudinal width of a region in which the magnetic field is not blocked by the superconducting shield structure 101, namely, Wₓ+λ_{L} and W_{y}+λ_{L}, respectively. The position of the opening HO shown in FIG. 9 conceptually shows the opening HO as arranged to face the SQUID SQ, however, the position of the opening HO is not limited thereto.

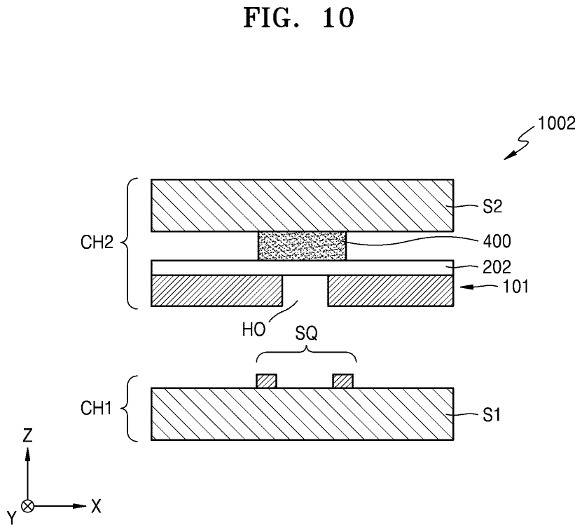

FIG. 10 is a cross-sectional view of a quantum computing apparatus 1002 according to one or more embodiments.

The quantum computing apparatus 1002 differs from the quantum computing apparatus 1001 of FIG. 8, in that an insulating material layer 202 is further arranged between the ferromagnetic substance 400 and the superconducting shield structure 101. The other elements are substantially the same as those of the quantum computing apparatus 1001 of FIG. 8.

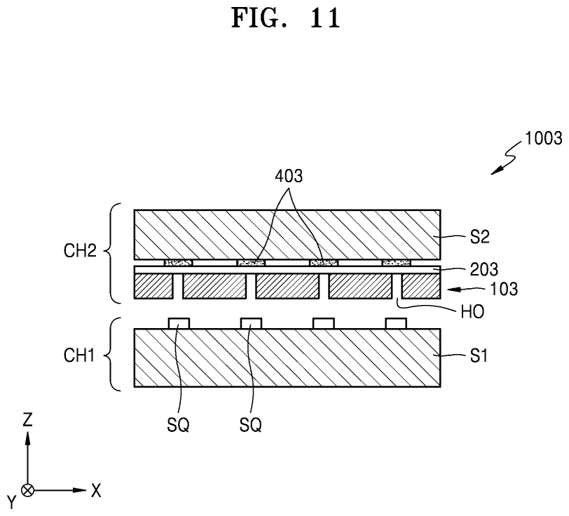

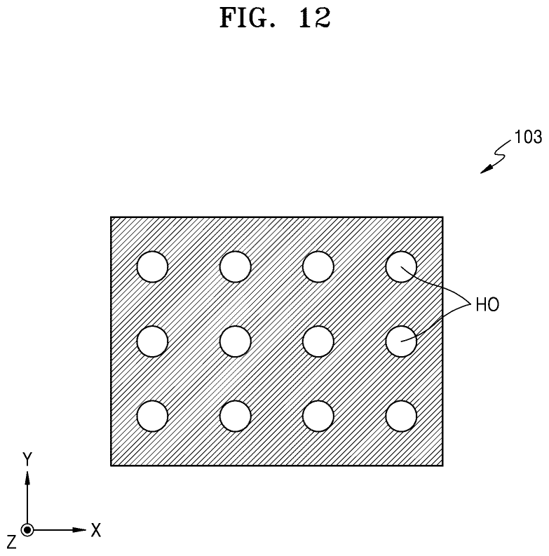

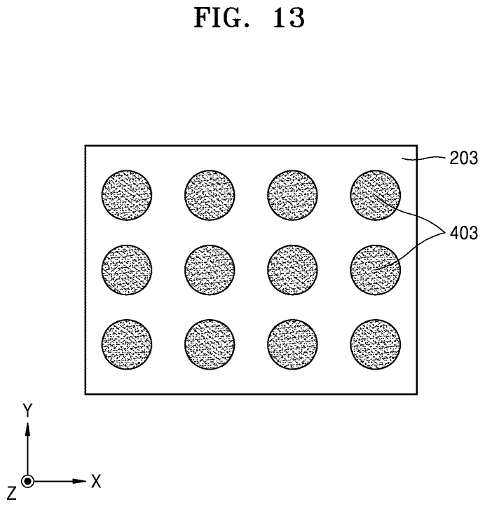

FIG. 11 is a cross-sectional view of another example of the quantum computing apparatus 1003, FIG. 12 is a plan view of the superconducting shield structure provided in the quantum computing apparatus of FIG. 11, and FIG. 13 is a plan view of the ferromagnetic substance arrangement provided in the quantum computing apparatus of FIG. 11.

The quantum computing apparatus 1003 includes the first chip device CH1 and the second chip device CH2 spaced apart from each other in a second direction (Z-direction). The first chip device CH1 includes the first substrate S1 and SQUIDs SQ disposed on the first substrate S1. The second chip device CH2 includes the second substrate S2 and a magnetic field generator and a superconducting shield structure 103 formed on the second substrate S2. The magnetic field generator includes ferromagnetic substances 403.

The quantum computing apparatus 1003 according to the example includes the superconducting shield structure 103 having a structure capable of reducing the noise transferred to the circuit elements connected to the plurality of SQUIDs SQ. The superconducting shield structure 103 may include multiple openings HO. The openings HO may be arranged to respectively face the SQUIDs SQ. The openings HO may be also arranged to face the ferromagnetic substances 403 in one-to-one correspondence.

The ferromagnetic substance 403 may have a saturation magnetization density that varies depending on an applied voltage (as described above with reference to FIG. 8), that is, a magnetic flux line formed around the ferromagnetic substance 403 may be controlled based on a voltage bias. The circuit elements for individually controlling the voltages applied to the ferromagnetic substances 403 may be arranged in the second substrate S2.

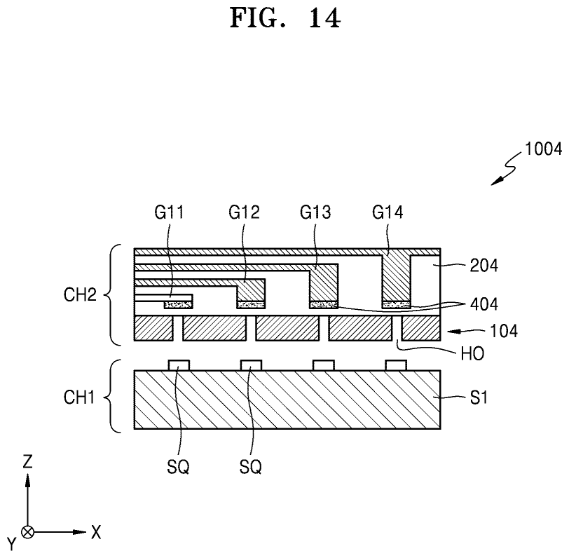

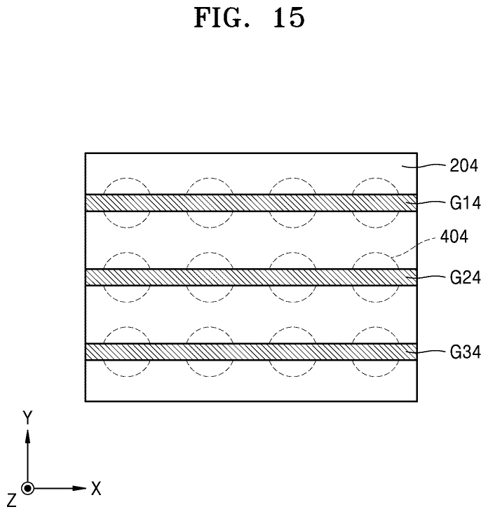

FIG. 14 is a cross-sectional view of a quantum computing apparatus 1004 according to another embodiment, and FIG. 15 is a plan view of the quantum computing apparatus 1004 of FIG. 14 viewed from above.

The quantum computing apparatus 1004 includes the first chip device CH1 including SQUIDs SQ, and the second chip device CH2 including a superconducting shield structure 104 provided with openings HO and ferromagnetic substances 404.

The second chip device CH2 may also include interconnections individually controlling the respective ferromagnetic substances 404. An insulating material layer 204 may be disposed on the superconducting shield structure 104. The ferromagnetic substances 404 may be arranged in the insulating material layer 204. And, gate electrodes G11, G12, G13, and G14 may be formed to respectively come into contact with the ferromagnetic substances 404.

One end portion of each of the gate electrodes G11, G12, G13, and G14 may be exposed to (or facing) outside of the insulating material layer 204. As shown in the drawings, the end portions of the gate electrodes G11, G12, G13, and G14 may be exposed on one side surface of the insulating material layer 204. The voltages applied to the ferromagnetic substances 404 may be individually controlled via the gate electrodes G11, G12, G13, and G14.

When the ferromagnetic substances 404 are arranged two-dimensionally in rows and columns, the gate electrodes connected to the ferromagnetic substances 404 in different columns may be formed at different heights (in the Z-direction) from each other. For example, the gate electrodes G11, G12, G13, and G14 respectively connected to the ferromagnetic substances 404 in a first row may be formed in different heights in the insulating material layer 204. The gate electrodes may be arranged with the same rule with respect to the ferromagnetic substances 404 located in a second row or a third row.

The arrangement of the gate electrodes is an example, and may be modified variously.

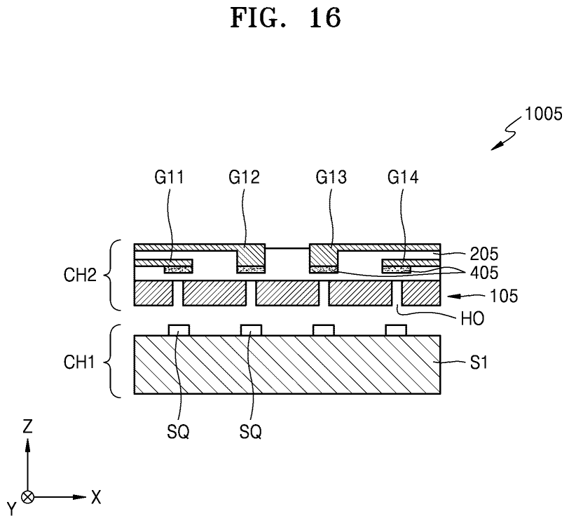

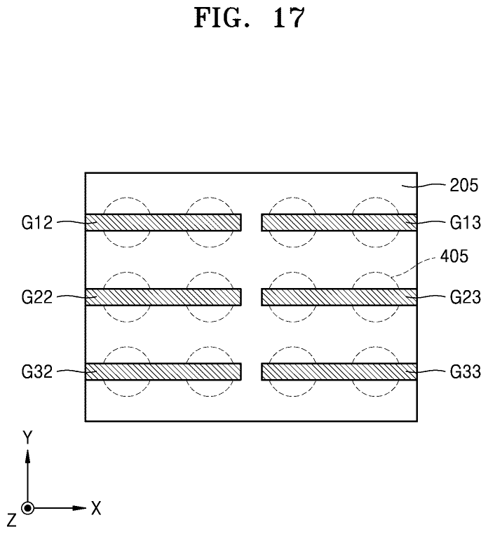

FIG. 16 is a cross-sectional view of a quantum computing apparatus 1005 according to one or more embodiments, and FIG. 17 is a plan view showing the quantum computing apparatus 1005 of FIG. 16 viewed from above.

The quantum computing apparatus 1005 includes the first chip device CH1 including a plurality of SQUIDs SQ, and the second chip device CH2 including a superconducting shield structure 105 provided with openings and ferromagnetic substances 405.

The second chip device CH2 is provided with the previously-mentioned interconnections for individually controlling the plurality of ferromagnetic substances 405, but detailed shapes of the interconnections are different from those of the quantum computing apparatus 1004 of FIG. 14.

To improve space utilization for forming the interconnections in the insulating material layer 205, the interconnections being respectively connected to the ferromagnetic substances 405, ends of the interconnections may be divided to be exposed to opposite sides of the insulating material layer 205.

When the ferromagnetic substances 405 are two-dimensionally arranged in rows and columns, some of the gate electrodes G11, G12, G13, and G14 respectively connected to the ferromagnetic substances 405 located in the first row may be exposed to a left surface of the insulating material layer 205 and some other may be exposed to a right surface of the insulating material layer 205. For example, the gate electrodes G11 and G12 may be formed at different heights in the insulating material layer 205 and then exposed to the left surface of the insulating material layer 205, and the gate electrodes G13 and G14 may be formed at different heights in the insulating material layer 205 and then exposed to the right surface of the insulating material layer 205. The gate electrodes in a second row or a third row may be arranged with the same design rule with respect to the ferromagnetic substances 405.

The arrangements of the gate electrodes individually controlling the plurality of ferromagnetic substances in FIGS. 14 to 17 are non-limiting examples and may be modified variously.

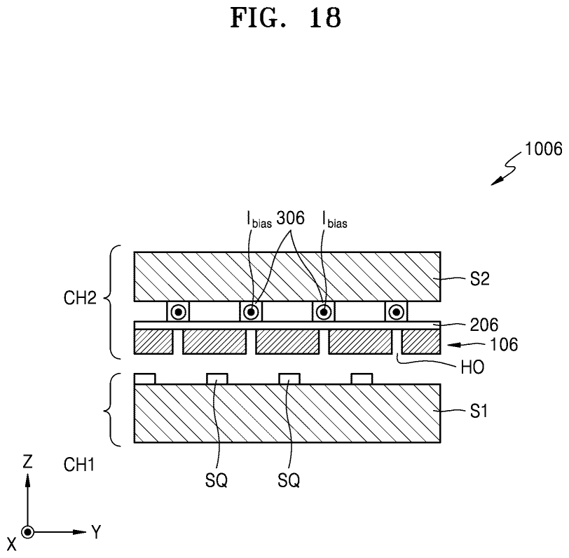

FIG. 18 is a cross-sectional view of a quantum computing apparatus 1006 according to one or more embodiments.

The quantum computing apparatus 1006 includes superconducting lines 306 as a magnetic field generator for forming magnetic fields in the SQUIDs SQ.

The quantum computing apparatus 1006 includes: the first chip device CH1, which includes SQUIDs SQ; and the second chip device CH2, which includes a superconducting shield structure 106 and superconducting lines 306.

The superconducting shield structure 106 includes openings HO. The openings HO may be arranged to be respectively misaligned with the SQUIDs SQ. As shown in the drawing, when viewed in the second direction (Z-direction), each of the openings HO may not entirely overlap the SQUID SQ. However, the embodiment is not limited thereto; a part of the opening HO and a part of the SQUID SQ may overlap each other.

The examples and embodiments of a quantum computing apparatus may have significantly reduced noise or crosstalk generated due to the magnetic field generator for controlling the frequency of a qubit.

The quantum computing apparatuses described above have a structure advantageous for expanding to multiple qubits, e.g., on a quantum computing chip.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A quantum computing apparatus comprising:
a substrate;
a superconducting quantum interferometric device disposed on the substrate and including a Josephson junction device;
a magnetic field generator configured to form a magnetic field, the magnetic field controlling what frequency the Josephson junction device operates with; and
a superconducting shield configured to shield a portion of the magnetic field formed by the magnetic field generator, the superconducting shield comprised of a superconducting material and having an opening.

2. The quantum computing apparatus of claim 1, wherein
the magnetic field generator is spaced apart from the substrate in a direction perpendicular to a plane of the substrate, and
the superconducting shield structure is arranged between the substrate and the magnetic field generator.

3. The quantum computing apparatus of claim 2, further comprising an insulating material layer arranged between the magnetic field generator and the superconducting shield.

4. The quantum computing apparatus of claim 1, wherein the superconducting quantum interferometric device has a shape forming a loop, and a position and a size of the opening in the superconducting shield are configured so that a magnetic field is generated in the loop of the superconducting quantum interferometric device by the magnetic field generator.

5. The quantum computing apparatus of claim 1, wherein the magnetic field generator includes a superconducting line comprised of a superconducting material and provides a current path in a first direction that is parallel to a planar surface of the substrate.

6. The quantum computing apparatus of claim 5, wherein, when viewed from a second direction that is perpendicular to the planar surface of the substrate,
a center of the superconducting shield and a center of the superconducting quantum interferometric device are not aligned with each other.

7. The quantum computing apparatus of claim 6, wherein the opening of the superconducting shield and the superconducting quantum interferometric device are arranged to not overlap each other when viewed from the second direction.

8. The quantum computing apparatus of claim 1, wherein the magnetic field generator includes a ferromagnetic substance forming a magnetic field by an applied voltage.

9. The quantum computing apparatus of claim 8, wherein the ferromagnetic substance has magnetic anisotropy in a direction perpendicular to a planar surface of the substrate.

10. The quantum computing apparatus of claim 8, wherein the ferromagnetic substance is arranged to face the opening of the superconducting shield.

11. The quantum computing apparatus of claim 10, wherein the opening of the superconducting shield is arranged to face the superconducting quantum interferometric device.

12. The quantum computing apparatus of claim 1, further comprising superconducting quantum interferometric devices.

13. The quantum computing apparatus of claim 12, wherein the opening is one of multiple openings in the superconducting shield.

14. The quantum computing apparatus of claim 13, wherein the magnetic field generator includes ferromagnetic substances facing the openings in one-to-one correspondence.

15. The quantum computing apparatus of claim 14, wherein the openings face the superconducting quantum interferometric devices in one-to-one correspondence.

16. The quantum computing apparatus of claim 14, further comprising
interconnections for individually applying voltages to the respective ferromagnetic substances.

17. The quantum computing apparatus of claim 16, further comprising an insulating material layer arranged on the superconducting shield structure to surround the ferromagnetic substances.

18. The quantum computing apparatus of claim 17, wherein the interconnections extend to be exposed to one side surface of the insulating material layer.

19. The quantum computing apparatus of claim 13, wherein the magnetic field generator includes superconducting lines.

20. The quantum computing apparatus of claim 19, wherein, when viewed from a direction perpendicular to a planar surface of the substrate, centers of the respective openings and centers of the respective superconducting quantum interferometric devices are not aligned with each other.
